(19) United States
(12) Patent Application Publication
(10) Pub. No.: US 2011/0305253 A1
(43) Pub. Date: Dec. 15, 2011

(54) SEMICONDUCTOR LASER MODULE

(75) Inventors: Go KOBAYASHI, Chiba (JP); Tatsuya KIMOTO, Chiba (JP); Toshio KIMURA, Chiba (JP); Takeshi AKUTSU, Tokyo (JP); Kazutaka NARA, Chiba (JP)

(73) Assignee: FURUKAWA ELECTRIC CO., LTD., Tokyo (JP)

(21) Appl. No.: 13/155,741

(22) Filed: Jun. 8, 2011

(30) Foreign Application Priority Data
Jun. 9, 2010 (JP) 2010-132120

(51) Int. Cl. H01S 5/024; H01S 5/40

(52) U.S. Cl. 372/36; 372/38.01; 372/50.12

(57) ABSTRACT

A semiconductor laser module includes a semiconductor laser section, a light selecting section, and an optical converting section. The semiconductor laser section includes a semiconductor laser substrate, a plurality of semiconductor laser elements mounted on the semiconductor laser substrate, and a first temperature adjusting element for adjusting temperature of the semiconductor laser elements. The light selecting section includes a light selecting element substrate and a light selecting element mounted on the light selecting element substrate and optically connected to the semiconductor laser elements, which selects laser light output from at least one of the semiconductor laser elements. The optical converting section includes an optical converting element substrate, an optical converting element mounted on the optical converting element substrate and optically connected to the light selecting element, which converts laser light output from the light selecting element, and a second temperature adjusting element for adjusting temperature of the optical converting element.

The contents of the following Japanese patent application are incorporated herein by reference: NO. 2010-132120 filed on Jun. 9, 2010.

### BACKGROUND

1. Technical Field

The present invention relates to a semiconductor laser element and to a semiconductor laser module that includes the semiconductor laser element and an element performing a predetermined process on laser light emitted from the semiconductor laser element.

2. Related Art

A typical semiconductor laser module includes a semiconductor laser element and a semiconductor optical amplifier (SOA) that amplifies laser light emitted from the semiconductor laser element or a semiconductor optical modulator that modulates laser light emitted from the semiconductor laser element or both, integrated on a single semiconductor substrate. Related technologies are described in Japanese Patent Application Laid-open No. 2001-85781, Japanese Patent Application Laid-open No. 2002-323685, Japanese Patent Application Laid-open No. 2007-250889, and Japanese Patent Application Laid-open No. 2009-93093, thr example.

In most cases, oscillation wavelength of a distributed feedback (DFB) laser element changes according to the temperature of the laser element. Accordingly, the wavelength of the laser light emitted from the DM laser element can be adjusted by operating the DFB laser element in a controlled temperature range from approximately 10° C. to 50° C. Similarly, the amplification efficiency of the semiconductor optical amplifier or the modulation efficiency of the semiconductor optical modulator decreases when the temperature of the semiconductor optical amplifier or the semiconductor optical modulator increases. Accordingly, in order to achieve output of a high-power laser light or laser light with a predetermined modulation factor, the temperature of the semiconductor optical amplifier or the semiconductor optical modulator should be kept constant at, for example, room temperature.

In the conventional semiconductor laser module, however, the semiconductor laser element and the semiconductor optical amplifier or the semiconductor optical modulator or both are integrated on a single semiconductor substrate. Therefore, when the semiconductor laser element operates at a high temperature in the conventional semiconductor laser module, the temperatures of the semiconductor optical amplifier or the semiconductor optical modulator increases due to the heat of the semiconductor laser element, thereby causing degradation of the amplification efficiency or the modulation efficiency. As a result, it is difficult to achieve output of a high-power laser light or laser light with the predetermined modulation factor. Therefore, a semiconductor laser module is desired that can separately control the temperatures of the semiconductor laser element, the semiconductor optical amplifier, and the semiconductor optical modulator to be within suitable ranges.

The present invention has been achieved in view of the above aspects, and it is an object of the present invention to provide a semiconductor laser module that can respectively control temperatures of a semiconductor laser element and an element that outputs converted light by converting laser light emitted by the semiconductor laser element to be in suitable temperature ranges.

### SUMMARY

According to one aspect of the present invention, there is provided a semiconductor laser module including a semiconductor laser section, a light selecting section, and an optical converting section. The semiconductor laser section includes a semiconductor laser substrate, a plurality of semiconductor laser elements mounted on the semiconductor laser substrate in an array, each emitting a laser light of different wavelength, and a first temperature adjusting element attached to the semiconductor laser substrate for adjusting temperature of the semiconductor laser elements. The light selecting section includes a light selecting element substrate and a light selecting element mounted on the light selecting element substrate and optically connected to the semiconductor laser elements, which selects laser light output from at least one of the semiconductor laser elements and outputting selected laser light. The optical converting section includes an optical converting element substrate, an optical converting element mounted on the optical converting element substrate and optically connected to the light selecting element, which converts the selected laser light output from the light selecting element and outputting converted light, and a second temperature adjusting element attached to the optical converting element substrate for adjusting temperature of the optical converting element.

The summary clause does not necessarily describe all necessary features of the embodiments of the present invention. The present invention may also be a sub-combination of the features described above.

### BRIEF DESCRIPTION OF THE DRAWINGS

FIG. 1 is a schematic cross-sectional view of an optical module according to a first embodiment of the present invention, as seen from above;

FIG. 2A is a top view of a semiconductor laser module according to the first embodiment;

FIG. 2B is a side view of the semiconductor laser module according to the first embodiment;

FIG. 3A is a top view of a semiconductor laser module according to a second embodiment of the present invention;

FIG. 3B is a side view of the semiconductor laser module according to the second embodiment;

FIG. 4A is a top view of a semiconductor laser module according to a third embodiment of the present invention; and

FIG. 4B is a side view of the semiconductor laser module according to the third embodiment.

### DESCRIPTION OF EXEMPLARY EMBODIMENTS

Exemplary embodiments of the present invention will be described in detail below with reference to accompanying drawings. However, the embodiments should not be construed to limit the invention. All the combinations of the features described in the embodiments are not necessarily essential to means provided by aspects of the invention.

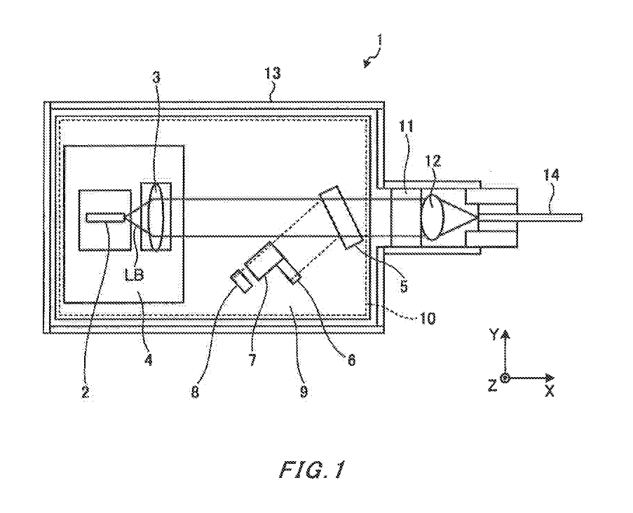

FIG. 1 is a schematic cross-sectional view of an optical module 1 according to a first embodiment of the present invention, as seen from above. In the following description, a direction in which the laser light is emitted, i.e. the optical axis direction, defines the X-axis, a direction perpendicular to the X-axis in the horizontal plane defines the Y-axis, and a direction normal to the XY-plane, i.e. the vertical direction, defines the Z-axis.

As shown in FIG. 1, the optical module 1 includes a semiconductor laser module 2, a collimating lens 3, a substrate 4, a beam splitter 5, a power-monitoring photodiode 6, an etalon filter 7, a wavelength-monitoring photodiode 8, a base plate 9, a temperature adjusting element 10, an optical isolator 11, a focusing lens 12, and a case 13 that houses these components.

The collimating lens 3 is arranged near a light emitting facet of the semiconductor laser module 2. The collimating lens 3 collimates a laser light LB emitted from the semiconductor laser module 2, and outputs the collimated laser light LB to the beam splitter 5. The substrate 4 has the semiconductor laser module 2 and the collimating lens 3 mounted on a horizontal installation surface thereof, which is in the XY-plane.

The beam splitter 5 transmits a portion of the laser light LB from the collimating lens 3 to the optical isolator 11, and splits the other portion of the laser light LB toward the power-monitoring photodiode 6 and the etalon filter 7. The power-monitoring photodiode 6 detects power of the laser light LB split by the beam splitter 5 and inputs an electric signal corresponding to the detected power to a control apparatus (not shown).

The etalon filter 7 has periodic transmission characteristics with respect to a wavelength of the laser light LB, and selectively transmits the laser light LB with a power corresponding to the transmission characteristics, to be input to the wavelength-monitoring photodiode 8. The wavelength-monitoring photodiode 8 detects the power of the laser light LB input from the etalon filter 7, and inputs an electric signal corresponding to the detected power to the control apparatus. The power of the laser light LB detected by the power-monitoring photodiode 6 and the wavelength-monitoring photodiode 8 is used by the control apparatus to perform wavelength locking control.

Specifically, in the wavelength locking control, the control apparatus controls the operation of the semiconductor laser module 2 such that a ratio between the power of the laser light LB detected by the power-monitoring photodiode 6 and the power of the laser light detected by the wavelength-monitoring photodiode 8 matches the ratio achieved when the oscillation wavelength and power of the laser light LB are desired values. In this way, the oscillation wavelength and power of the laser light LB can be controlled to be desired values.

The base plate 9 has a horizontal installation surface in the XY-plane, on which the substrate 4, the beam splitter 5, the power-monitoring photodiode 6, the etalon filter 7, and the wavelength-monitoring photodiode 8 are mounted. The temperature adjusting element 10 has a horizontal installation surface in the XY-plane, on which the base plate 9 is mounted. The temperature adjusting element 10 is used to control the selected wavelength of the etalon filter 7 by adjusting the temperature of the etalon filter 7 via the base plate 9. The temperature adjusting element 10 may be a Peltier device. The optical isolator 11 restricts back-reflected light from the optical fiber 14 from coupling with the laser light LB. The focusing lens 12 couples the laser light LB transmitted by the beam splitter 5 into the optical fiber 14.

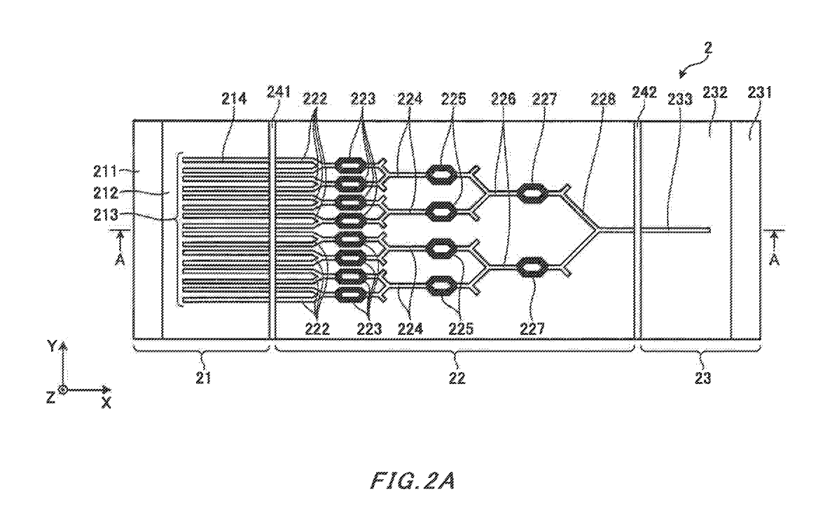

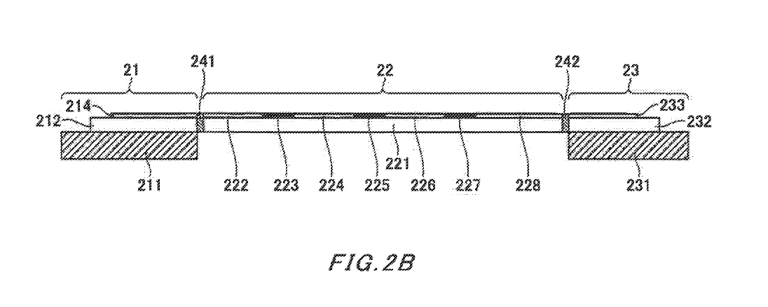

FIG. 2A is a top view of the semiconductor laser module 2 according to the first embodiment. FIG. 2B is a side view of the semiconductor laser module 2 shown in FIG. 2A. As shown in FIGS. 2A and 2B, the semiconductor laser module 2 according to the first embodiment includes a semiconductor laser section 21, a light selecting section 22, and an amplifying section 23.

The semiconductor laser section 21 includes a temperature adjusting element 211, a semiconductor laser substrate 212 mounted on the temperature adjusting element 211, and a semiconductor laser array 213 formed on the semiconductor laser substrate 212. The temperature adjusting element 211 controls the temperature of the semiconductor laser array 213 via the semiconductor laser substrate 212, according to a control signal from a control apparatus (not shown).

The temperature adjusting element 211 functions as a first temperature adjusting element. The temperature adjusting element 211 may be a Peltier device, for example. The semiconductor laser array 213 includes a plurality (16 in the present embodiment) of longitudinal single-mode semiconductor laser elements 214 (hereinafter, “semiconductor laser elements 214”) arranged in an array with a wavelength interval of for example, 3 nanometers to 4 nanometers, and each of the semiconductor laser elements 214 emits laser light with a different wavelength from a facet thereof. The semiconductor laser elements 214 are distributed feedback (DFB) laser elements, and the oscillation wavelengths thereof are controlled by adjusting the temperatures thereof.

More specifically, each semiconductor laser element 214 can change the oscillation wavelength in a range of approximately 3 nanometers to 4 nanometers, and the oscillation wavelengths of the semiconductor laser elements 214 are designed to have intervals of approximately 3 nanometers to 4 nanometers therebetween. Therefore, by switching the semiconductor laser elements 214 to be driven while controlling the temperatures thereof, the semiconductor laser array 213 can emit the laser light LB in a continuous wavelength band that is broader than the hand of a single semiconductor laser element.

By integrating ten or more semiconductor laser elements 214 with oscillation wavelengths that can be changed in a range from 3 nanometers to 4 nanometers and arranging them with an interval of, for example, 3 nanometers to 4 nanometers, the semiconductor laser section 21 can change the wavelength of the laser light over a wavelength region of 30 nanometers or more. As a result, the semiconductor laser section 21 can output laser light that covers the entire wavelength band used for WDM communication, which can be a C-band from 1.53 micrometers to 1.56 micrometers or an L-band from 1.57 micrometers to 1.61 micrometers, for example.

The light selecting section 22 includes a light selecting element substrate 221, and optical waveguides 222, 224, 226, and 228 and Mach-Zehnder interferometer (WI) elements 223, 225, and 227 formed on the light selecting element substrate 221, The light selecting element substrate 221 is affixed to the semiconductor laser substrate 212 by a UV-curing resin 241 that has characteristics to transmit laser lights with the wavelengths output from the semiconductor laser elements 214. The UV-curing resin 241 may be acrylic resin, epoxy resin, polyester resin, or the like.

The optical waveguides 222 are optically connected to the light emitting facets of the semiconductor laser elements 214 by the UV-curing resin 241. The optical waveguides 222 guide the laser lights emitted from the semiconductor laser elements 214 to the MZI elements 223. Each MZI element 223 is optically connected to two adjacent optical waveguides 222, selects the laser light guided from one of the two optical waveguides 222, and outputs the selected laser light. Each WI element 223 may be optically connected to three or more optical waveguides 222, and may select the laser light guided from at least one of the three or more optical waveguides 222 to be output.

The optical waveguides 224 guide the laser light from the MZI elements 223 to the MZI elements 225. Each MZI element 225 is optically connected to an optical waveguide 224, selects the laser light guided from the optical waveguide 224, and outputs the selected laser light. The optical waveguides 226 guide the laser light output from the MZI elements 225 to the MZI elements 227. Each MZI element 227 is optically connected to an optical waveguide 226, selects the laser light guided from the optical waveguide 226, and outputs the selected laser light. The optical waveguide 228 guides the laser light selected and output by the MZI elements 227 to the amplifying section 23. In this way, the light selecting section 22 can be formed by Mach-Zehnder light selecting elements formed of planer lightwave circuits (PLCs) with 16 inputs and 1 output. Furthermore, the light selecting section 22 can select the laser light emitted by one of the (16 in the present embodiment) semiconductor laser elements 214, and output the selected laser light.

The amplifying section 23 includes a temperature adjusting element 231, an amplifier substrate 232 mounted on the temperature adjusting element 231, and a semiconductor optical amplifier 233 formed on the amplifier substrate 232. The temperature adjusting element 231 controls the temperature of the semiconductor optical amplifier 233 via the amplifier substrate 232, according to a control signal from the control apparatus. The temperature adjusting element 231 functions as a second temperature adjusting element. The temperature adjusting element 231 may be a Peltier device, for example.

The amplifier substrate 232 is affixed to the light selecting element substrate 221 by a UV-curing resin 242. The UV-curing resin 242 has characteristics to transmit laser light with the wavelengths output by the optical waveguide 228. The amplifier substrate 232 functions as an optical converting element substrate. The semiconductor optical amplifier 233 is optically connected to the optical waveguide 228 via the UV-curing resin 242. The semiconductor optical amplifier 233 amplifies the laser light guided by the optical waveguide 228, and emits the amplified laser light in the X-axis direction.

When manufacturing the semiconductor laser module 2 having the above structure, first, the semiconductor laser array 213 is formed on the semiconductor laser substrate 212, and then the light selecting elements that select and output the laser light emitted from the semiconductor laser array 213 are formed on the light selecting element substrate 221. Next, the semiconductor optical amplifier 233 that amplifies the laser light selected and output by the light selecting elements is formed on the amplifier substrate 232.

Next, the semiconductor laser substrate 212 and the light selecting element substrate 221 are affixed to each other by the UV-curing resin 241, such that the laser light emitting facets of the semiconductor laser array 213 are optically connected to the light selecting elements. Furthermore, the light selecting element substrate 221 and the amplifier substrate 232 are affixed to each other by the UV-curing resin 242, such that the light selecting elements are optically connected to the semiconductor optical amplifier 233. Finally, the semiconductor laser substrate 212 is bonded on the temperature adjusting element 211 that controls the temperature of the semiconductor laser array 213, and the amplifier substrate 232 is bonded on the temperature adjusting element 231 that controls the temperature of the semiconductor optical amplifier 233.

As made clear from the above description, in the semiconductor laser module 2 according to the first embodiment, the temperature of the semiconductor laser elements 214 and the temperature of the semiconductor optical amplifier 233 can be adjusted by using the temperature adjusting element 211 and the temperature adjusting element 231, respectively. Furthermore, by interposing the light selecting element substrate 221 including the light selecting elements between the semiconductor laser substrate 212 including the semiconductor laser elements 214 and the amplifier substrate 232 including the semiconductor optical amplifier 233 in the semiconductor laser module 2, the thermal interference between the semiconductor laser elements 214 and the semiconductor optical amplifier 233 can be decreased. As a result, the temperature of the semiconductor laser elements 214 and the temperature of the semiconductor optical amplifier 233 can be controlled to be within suitable ranges.

In the semiconductor laser module 2 according to the first embodiment, since the temperature increase of the semiconductor optical amplifier 233 occurring when the semiconductor laser elements 214 are driven at a high temperature is suppressed, a high-power laser light can be output. In the semiconductor laser module 2 according to the first embodiment, the selection and output of laser light from the semiconductor laser elements 214 is achieved by using the Mach-Zehnder light selecting elements instead of a multi-mode interferometer (MMI) coupler. Therefore, even though the semiconductor laser elements 214 and the semiconductor optical amplifier 233 are formed on different substrates, the connection loss from the semiconductor laser elements 214 to the semiconductor optical amplifier 233 can be decreased.

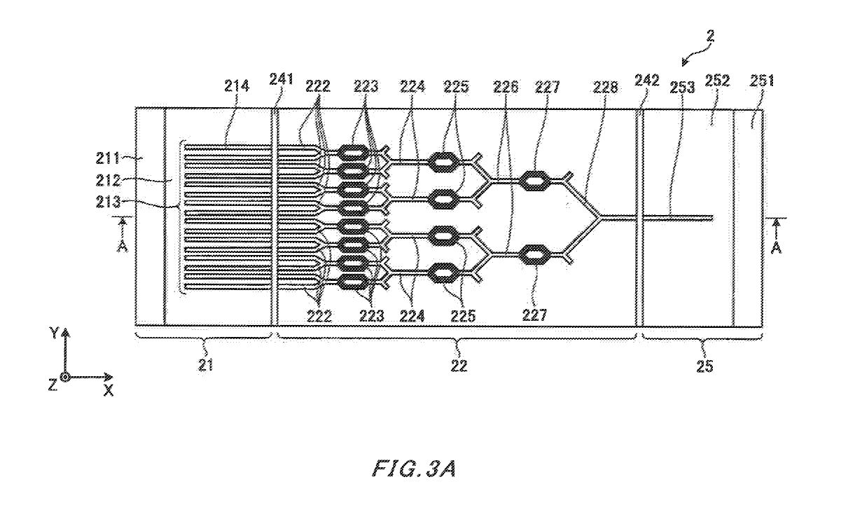

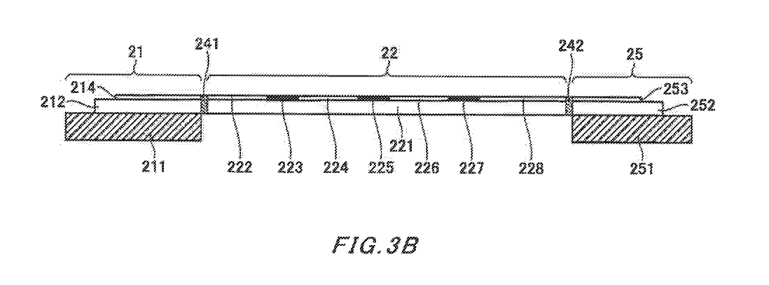

FIG. 3A is a top view of a semiconductor laser module 2 according to a second embodiment of the present invention. FIG. 3B is a side view of the semiconductor laser module 2 shown in FIG. 3A. As shown in FIGS. 3A and 3B, the semiconductor laser module according to the second embodiment includes a semiconductor laser section 21, a light selecting section 22, and a modulating section 25. The semiconductor laser section 21 and the light selecting section 22 have the same structure as those in the first embodiment, and the following description includes only differing points.

The modulating section 25 includes a temperature adjusting element 251, a modulator substrate 252 mounted on the temperature adjusting element 251, and a semiconductor optical modulator 253 formed on the modulator substrate 252. The temperature adjusting element 251 controls the temperature of the semiconductor optical modulator 253 via the modulator substrate 252, according to a control signal from a control apparatus (not shown). The temperature adjusting element 251 functions as a second temperature adjusting element or a third temperature adjusting element.

The temperature adjusting element 251 may be a Peltier device, for example. The modulator substrate 252 is affixed to a light selecting element substrate 221 by a UV-curing resin 242. The modulator substrate 252 functions as an optical converting element substrate. The semiconductor optical modulator 253 is optically connected to the optical waveguide 228 via the UV-curing resin 242. The semiconductor optical modulator 253 modulates the laser light guided by the optical waveguide 228, and emits the modulated laser light in the X-axis direction.

When manufacturing the semiconductor laser module 2 having the above structure, first, a semiconductor laser array 213 is formed on a semiconductor laser substrate 212, and then the light selecting elements that select and output at least one of the laser lights emitted from the semiconductor laser array 213 are formed on the light selecting element substrate 221. Next, the semiconductor optical modulator 253 that modulates the laser light selected and output by the light selecting elements is formed on the modulator substrate 252.

Next, the semiconductor laser substrate 212 and the light selecting element substrate 221 are affixed to each other by a TN-curing resin 241, such that the laser light emitting facets of the semiconductor laser array 213 are optically connected to the light selecting elements. Furthermore, the light selecting element substrate 221 and the modulator substrate 252 are affixed to each other by the UV-curing resin 242, such that the light selecting elements are optically connected to the semiconductor optical modulator 253, Finally, the semiconductor laser substrate 212 is bonded on a temperature adjusting element 211 that controls the temperature of the semiconductor laser array 213, and the modulator substrate 252 is bonded on the temperature adjusting element 251 that controls the temperature of the semiconductor optical modulator 253.

As made clear from the above description, in the semiconductor laser module 2 according to the second embodiment, the temperature of semiconductor laser elements 214 and the temperature of the semiconductor optical modulator 253 can be adjusted by using the temperature adjusting element 211 and the temperature adjusting element 251, respectively.

Furthermore, by interposing the light selecting element substrate 221 including the light selecting elements between the semiconductor laser substrate 212 including the semiconductor laser elements 214 and the modulator substrate 252 including the semiconductor optical modulator 253 in the semiconductor laser module 2, the thermal interference between the semiconductor laser elements 214 and the semiconductor optical modulator 253 can be decreased. As a result, the temperature of the semiconductor laser elements 214 and the temperature of the semiconductor optical modulator 253 can be separately controlled to be within suitable ranges.

In the semiconductor laser module 2 according to the second embodiment, since the temperature increase of the semiconductor optical modulator 253 occurring when the semiconductor laser elements 214 are driven at a high temperature is suppressed, laser light with a modulation factor near the design value can be output. In the semiconductor laser module 2 according to the second embodiment, the selection and output of laser light from the semiconductor laser elements 214 is achieved by using Mach-Zehnder light selecting elements instead of an MMI coupler. Therefore, even though the semiconductor laser elements 214 and the semiconductor optical modulator 253 are formed on different substrates, the connection loss from the semiconductor laser elements 214 to the semiconductor optical modulator 253 can be decreased.

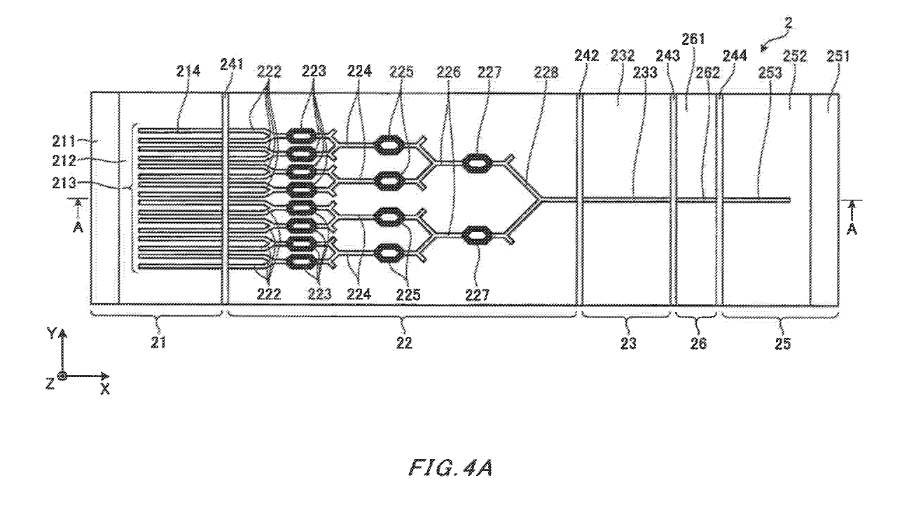

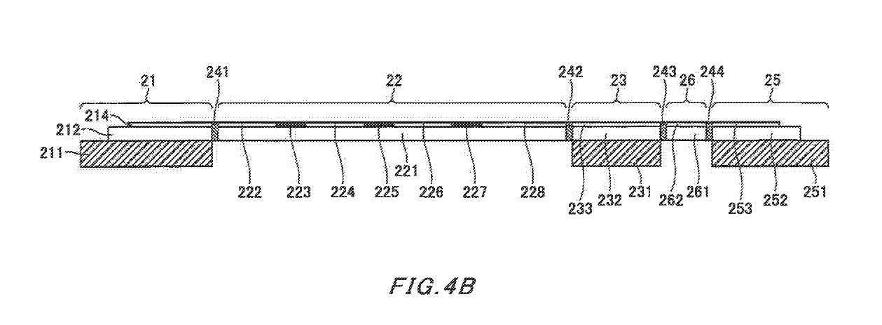

FIG. 4A is a top view of a semiconductor laser module 2 according to a third embodiment of the present invention. FIG. 4B is a side view of the semiconductor laser module 2 shown in FIG. 4A. As shown in FIGS. 4A and 4B, the semiconductor laser module 2 according to the third embodiment includes a semiconductor laser section 21, a light selecting section 22, an amplifying section 23, a modulating section 25, and a waveguide section 26. The semiconductor laser section 21, the light selecting section 22, and the amplifying section 23 have the same structure as those in the first embodiment, and the following description includes only differing points.

The waveguide section 26 includes a waveguide substrate 261 and an optical waveguide 262 formed on the waveguide substrate 261. The waveguide substrate 261 is affixed to an amplifier substrate 232 by a UV-curing resin 243. The optical waveguide 262 is optically connected to a semiconductor optical amplifier 233 via the UV-curing resin 243. The optical waveguide 262 guides the laser light amplified by the semiconductor optical amplifier 233 to the modulating section 25.

The modulating section 25 includes a temperature adjusting element 251, a modulator substrate 252 mounted on the temperature adjusting element 251, and a semiconductor optical modulator 253 formed on the modulator substrate 252. The temperature adjusting element 251 controls the temperature of the semiconductor optical modulator 253 via the modulator substrate 252, according to a control signal from a control apparatus (not shown). The modulator substrate 252 is affixed to the waveguide substrate 261 by a UV-curing resin 244. The semiconductor optical modulator 253 is optically connected to the optical waveguide 262 via the UV-curing resin 244. The semiconductor optical modulator 253 modulates the laser light guided by the optical waveguide 262, and outputs the modulated laser light in the X-axis direction.

When manufacturing the semiconductor laser module 2 having the above structure, first, a semiconductor laser array 213 is formed on the semiconductor laser substrate 212, and then light selecting elements that select and output at least one of the laser lights emitted from the semiconductor laser array 213 are formed on the light selecting element substrate 221. Next, the semiconductor optical amplifier 233 that amplifies the laser light selected and output by the light selecting elements is formed on the amplifier substrate 232, and the optical waveguide 262 that guides the laser light amplified by the semiconductor optical amplifier 233 is formed on the waveguide substrate 261.

Next, the semiconductor optical modulator 253 that modulates the laser light guided by the optical waveguide 262 is formed on the modulator substrate 252. The semiconductor laser substrate 212 and the light selecting element substrate 221 are then affixed to each other by a UV-curing resin 241, such that the laser light emitting facets of the semiconductor laser array 213 are optically connected to the light selecting elements. Furthermore, the light selecting element substrate 221 and the amplifier substrate 232 are affixed to each other by a UV-curing resin 242, such that the light selecting elements are optically connected to the semiconductor optical amplifier 233.

Next, the amplifier substrate 232 and the waveguide substrate 261 are affixed to each other by the UV-curing resin 243, such that the semiconductor optical amplifier 233 is optically connected to the optical waveguide 262. Furthermore, the waveguide substrate 261 and the modulator substrate 252 are affixed to each other by the UV-curing resin 244, such that the optical waveguide 262 is optically connected to the semiconductor optical modulator 253. Finally, the semiconductor laser substrate 212 is bonded on a temperature adjusting element 211 that controls the temperature of the semiconductor laser array 213, the amplifier substrate 232 is bonded on a temperature adjusting element 231 that controls the temperature of the semiconductor optical amplifier 233, and the modulator substrate 252 is bonded on the temperature adjusting element 251 that controls the temperature of the semiconductor optical modulator 253.

As made clear from the above description, in the semiconductor laser module 2 according to the third embodiment, the temperature of the semiconductor laser elements 214, the temperature of the semiconductor optical amplifier 233, and the temperature of the semiconductor optical modulator 253 can be adjusted by using the temperature adjusting element 211, the temperature adjusting element 231, and the temperature adjusting element 251 corresponding respectively to the semiconductor laser elements 214, the semiconductor optical amplifier 233, and the semiconductor optical modulator 253.

Furthermore, by interposing the light selecting element substrate 221 including the light selecting elements between the semiconductor laser substrate 212 including the semiconductor laser elements 214 and the amplifier substrate 232 including the semiconductor optical amplifier 233 and also interposing the waveguide substrate 261 including the optical waveguide 262 between the amplifier substrate 232 including the semiconductor optical amplifier 233 and the modulator substrate 252 including the semiconductor optical modulator 253 in the semiconductor laser module 2, the thermal interference between the semiconductor laser elements 214, the semiconductor optical amplifier 233, and the semiconductor optical modulator 253 can be decreased. As a result, the temperatures of the semiconductor laser elements 214, the semiconductor optical amplifier 233, and the semiconductor optical modulator 253 can each be controlled to be within a suitable range.

In the semiconductor laser module according to the third embodiment, since the temperature increase of the semiconductor optical amplifier 233 and the semiconductor optical modulator 253 occurring when the semiconductor laser elements 214 are driven at a high temperature is suppressed, high-power laser light with a modulation factor near the design value can be output. In the semiconductor laser module according to the third embodiment, the selection and output of laser light from the semiconductor laser elements 214 is achieved by using Mach-Zehnder light selecting elements instead of an MMI coupler. Therefore, even though the semiconductor laser elements 214 and the semiconductor optical amplifier 233 are formed on different substrates, the connection loss from the semiconductor laser elements 214 to the semiconductor optical amplifier 233 can be decreased.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

As made clear from the above, the embodiments of the present invention can provide a semiconductor laser module that can control the temperature of semiconductor laser elements and the temperature of elements performing predetermined processes on laser light emitted from the semiconductor laser elements to each be in a suitable range.

What is claimed is:

1. A semiconductor laser module comprising:
a semiconductor laser section including
a semiconductor laser substrate,
a plurality of semiconductor laser elements mounted on the semiconductor laser substrate in an array, each of the semiconductor laser elements emitting a laser light of different wavelength, and
a first temperature adjusting element attached to the semiconductor laser substrate for adjusting temperature of the semiconductor laser elements;
a light selecting section including
a light selecting element substrate,
a light selecting element mounted on the light selecting element substrate and optically connected to the semiconductor laser elements, the light selecting element selecting laser light output from at least one of the semiconductor laser elements and outputting selected laser light; and
an optical converting section including
an optical converting element substrate,
an optical converting element mounted on the optical converting element substrate and optically connected to the light selecting element, the optical converting element converting the selected laser light output from the light selecting element and outputting converted light, and
a second temperature adjusting element attached to the optical converting element substrate for adjusting temperature of the optical converting element.

2. The semiconductor laser module according to claim 1, further comprising:
a first bonding section that bonds the semiconductor laser substrate to the light selecting element substrate, the first bonding section being optically transparent to wavelengths of the laser lights emitted from the semiconductor laser elements; and
a second bonding section that bonds the light selecting element substrate to the optical converting element substrate, the second bonding section being optically transparent to wavelength of the selected laser light output from the light selecting element.

3. The semiconductor laser module according to claim 1, wherein the optical converting element is a semiconductor optical amplifier that amplifies the selected laser light output from the light selecting element and outputs amplified laser light.

4. The semiconductor laser module according to claim 2, wherein the optical converting element is a semiconductor optical amplifier that amplifies the selected laser light output from the light selecting element.

5. The semiconductor laser module according to claim 1, wherein the optical converting element is a semiconductor optical modulator that modulates the selected laser light output from the light selecting element.

6. The semiconductor laser module according to claim 2, wherein the optical converting element is a semiconductor optical modulator that modulates the selected laser light output from the light selecting element.

7. The semiconductor laser module according to claim 3, further comprising:
a waveguide section including
a waveguide substrate,
an optical waveguide mounted on the waveguide substrate and optically connected to the semiconductor optical amplifier, the optical waveguide guiding the amplified laser light output from the semiconductor optical amplifier; and
a modulator section including
a modulator substrate,
a semiconductor optical modulator mounted on the modulator substrate and optically connected to the optical waveguide, the semiconductor optical modulator modulating the amplified laser light guided by the optical waveguide, and
a third temperature adjusting element attached to the modulator substrate for adjusting temperature of the semiconductor optical modulator.

8. The semiconductor laser module according to claim 4, further comprising:
a waveguide section including
a waveguide substrate,
an optical waveguide mounted on the waveguide substrate and optically connected to the semiconductor optical amplifier, the optical waveguide guiding the amplified laser light output from the semiconductor optical amplifier; and
a modulator section including
a modulator substrate,
a semiconductor optical modulator mounted on the modulator substrate and optically connected to the optical waveguide, the semiconductor optical modulator modulating the amplified laser light guided by the optical waveguide, and
a third temperature adjusting element attached to the modulator substrate for adjusting temperature of the semiconductor optical modulator.

9. The semiconductor laser module according to claim 8, further comprising:
a third bonding section that bonds the optical converting element substrate to the waveguide substrate, the third bonding section being optically transparent to wavelength of the amplified laser light output from the semiconductor optical amplifier; and
a fourth bonding section that bonds the waveguide substrate to the modulator substrate, the fourth bonding section being optically transparent to wavelength of laser light output from the optical waveguide.

10. The semiconductor laser module according to claim 1, wherein the semiconductor laser elements are distributed feedback semiconductor laser elements.

11. The semiconductor laser module according to claim 1, wherein the light selecting element includes a Mach-Zehnder interferometer.
